(19) United States
(12) Patent Application Publication
(10) Pub. No.: US 2016/0259022 A1
(43) Pub. Date: Sep. 8, 2016

(54) RECORDING AND EVALUATING MAGNETIC RESONANCE SIGNALS OF A FUNCTIONAL MAGNETIC RESONANCE EXAMINATION

(71) Applicant: Thomas Beck, Erlangen (DE)

(72) Inventor: Thomas Beck, Erlangen (DE)

(21) Appl. No.: 15/061,237

(22) Filed: Mar. 4, 2016

(30) Foreign Application Priority Data
Mar. 5, 2015 (DE) 102015203938.2

(51) Int. Cl. G01R 33/48; G01R 33/50

(52) U.S. Cl. CPC G01R 33/4806; G01R 33/50

(57) ABSTRACT

Recording and evaluating magnetic resonance signals of a functional magnetic resonance examination of a patient is provided. A region of the patient's brain is influenced during at least two time intervals. During the first time interval, the influencing takes place in accordance with a first way of stimulation and during a second time interval in accordance with a second way of stimulation, wherein the first and the second way of stimulation differ. While the at least two time intervals magnetic resonance signals are acquired from the region of the patient's brain by means of a pseudo-random stimulation sequence, the acquired magnetic resonance signals are evaluated.

### CROSS-REFERENCE TO RELATED APPLICATION

This application claims priority under 35 U.S.C. §119 to German Patent Application No. 102015203938.2, filed on Mar. 5, 2015, the entire content of which is incorporated herein by reference.

### FIELD

The present disclosure relates to a method, a magnetic resonance device and a computer program product for recording and evaluating magnetic resonance signals of a functional magnetic resonance examination of a patient.

### BACKGROUND

Magnetic Resonance Imaging (MRI) is a known technique for creating images of the inside of a body of an examination object. Rapidly switched gradient fields are created by a gradient system of the magnetic resonance device and superimposed onto a static basic magnetic field in a magnetic resonance device. Furthermore, RF pulses are irradiated into the examination object by a radio frequency antenna unit of the magnetic resonance device to trigger magnetic resonance signals, and the triggered magnetic resonance signals are recorded to create magnetic resonance images.

By the functional magnetic resonance examination of a patient, also referred to as functional magnetic resonance imaging (fMRI), physiological functions inside the body of the patient can be represented with the methods of MRI. In such cases a BOLD (Blood Oxygenation Level Dependent) contrast can be used, causing a change of the T2* time between deoxygenated hemoglobin and oxygenated hemoglobin. Oxygenated hemoglobin is diamagnetic, while deoxygenated hemoglobin is paramagnetic. The paramagnetic deoxhemoglobin causes magnetic field inhomogeneities in the immediate vicinity, reducing the T2* time. Gradient echo recordings are sensitive in relation to T2* times and can therefore represent the change in the T2* time.

When an fMRI is being carried out, an increase in an amplitude of the magnetic resonance signal can be observed in active regions of the brain due to neuronal activity, leading to increased oxygen consumption and an increased proportion of deoxygenated hemoglobin. However, the effect is overcompensated for by an increased blood flow. Oxygenated hemoglobin flows in again causing the t2* time of the active region to rise again and thus leads to an increased signal. The response function of an activity stimulus is called the Hemodynamic Response Function (HRF).

The methods described above allow the expected, temporal intensity development of a region of the brain to a defined stimulus to be determined. Thus, for a given time series of image data and/or imagings that have been recorded while an fMRI experiment was being carried out, the active brain regions may be determined by a correlation analysis. A frequently used method is the General Linear Model (GLM), which establishes the correlation between the change in intensity expected and the actual intensity curve measured.

When an fMRI examination is being carried out, individual regions of the brain are explicitly stimulated and detected as described above. A typical carrying out of an fMRI experiment is for example the acquisition of a time series, including 60 image volumes (repetition time TR of a volume appr. 3 seconds). The time series has alternating active phases and idle phase, for example 10 volumes idle, 10 active, 10 idle, 10 active, 10 idle, 10 active. The description of the order of stimuli is called the paradigm. In the active phases the region of the brain to be examined is stimulated, this being able to be done for example by visual stimulation, (flickering checkerboard pattern on a monitor), motor activity (explicit movement of the fingers), stimulation of the voice center (completion of sentences) or many other known experiments. For a good result, additional stimuli are minimized in order to selectively activate the relevant region.

### SUMMARY AND DESCRIPTION

The object of the present disclosure is to provide a method and a device improving the recording and evaluation of magnetic resonance signals of a functional magnetic resonance examination of a patient.

Accordingly, the disclosed method for recording and evaluating magnetic resonance signals of a functional magnetic resonance examination of a patient includes influencing at least one area of the brain of the patient within at least two time intervals. Within a first time interval of the at least two time intervals, the influencing is done in accordance with a first way of stimulation. Within a second time interval of the at least two time intervals is performed using a second way of stimulation. The first and second way of stimulation differ from one another. During the at least two time intervals, magnetic resonance signals are acquired from the at least one region of the patient's brain by a pseudo-random stimulation sequence. The acquired magnetic resonance signals are evaluated.

A time interval may be a time segment and/or an epoch and/or a phase, especially an idle phase that may also be a passive phase or baseline, and/or active phase of a paradigm, embodied in accordance with a blocked design. Normal time intervals amount to several seconds. The time intervals may follow on immediately from one another, e.g., without any temporal spaces between the time intervals.

A region of the brain is a spatial area of a human or animal brain. The way one or more brain region is stimulated within a time interval is a result of how the at least one brain region is influenced. Brain regions can be influenced by different stimuli, for example visual, haptic, acoustic, olfactory, gustatory, and/or electrical stimuli. In addition, brain regions can be stimulated by motor activity (e.g. explicit movement of one or more parts of the body such as the fingers), by stimulation of a speech center (e.g. completion of sentences), and/or by many other known stimulations. Stimulation of brain regions may be employed during an active phase.

Stimulating the brain during a time interval may be a constant stimulus (e.g., a tone that remains the same), acting on the patient's during the time interval. The way that the brain is stimulated during a time interval may be a repeated stimulus (e.g. repeated tapping of fingers against thumb), acting on the patient during the time interval. More complex stimulation may be used (e.g., a combination and/or an overlaying of constant and repeated stimuli).

Stimulation no explicit influencing and/or stimulation, especially by external stimuli. Unintentional stimuli being supplied to the patient, may include undesired and/or unchecked noises made by a conventional acquisition mode during a functional magnetic resonance examination. Stimulation without explicit influencing and/or stimulation may be employed during an idle phase.

The stimulation used for consecutive time intervals may differ. For example, an active phase may follow an idle phase, and/or an idle phase may follow an active phase. An alternating sequence of two different forms of stimulations can also be referred to as an A/B block. However, more than two time intervals may be arranged one after another, wherein each of the time intervals has a way of stimulation differing from the other time intervals. For example, an idle phase may be called a first time interval, a first active phase may be called second time interval, and a second active phase may be called a third time interval. The time intervals may be repeated once or a number of times.

The magnetic resonance signals are acquired via a pseudo-random stimulation sequence, also able to be called a pseudo-randomized stimulation sequence, during the at least two time intervals. A stimulation sequence is often also referred to as a pulse sequence and/or MR sequence and/or sequence.

A conventional functional magnetic resonance examination is carried out by a regular stimulation sequence. Segments of the stimulation sequence may be repeated and only a few parameters (e.g., one or two parameters, such as a phase encoding gradient and/or a slice selection gradient) are varied slightly from segment to segment. The stimulation sequence of conventional functional magnetic resonance examinations, a k-space (also called a local frequency space) is sampled completely or partly, producing a more or less regular sampling pattern.

The segment of the stimulation sequence can be understood as a part of the stimulation sequence introduced by an initial stimulation pulse to stimulate specific nuclear spins. The pulse is followed by one or more readout processes, measuring the resonances caused by the initial stimulation pulse. Further RF pulses and/or gradient pulses may be switched between the initial stimulation pulse and the last of the readout processes in order to modify the resonance signals.

In a stimulation sequence a plurality of these types of segments may be employed one after another. Multiple segments of a stimulation sequence may be nested temporally within one another (e.g., in a multi-slice sequence). The time interval between two initial stimulation pulses is sometimes also referred to as the repetition time, TR.

By contrast, the stimulation sequence of the disclosed embodiments is pseudo-random, enabling multiple stimulation parameters in the course of the stimulation sequence to be greatly and/or irregularly varied. The number of degrees of freedom in the stimulation sequence is advantageously increased, since given boundary conditions of conventional stimulation sequences for functional magnetic resonance examinations are dispensed with. As a consequence, the flexibility of the functional magnetic resonance examination is also increased, so that a greater palette of examination options may be made available.

The pseudo-random stimulation sequence may be configured to establish at least one tissue parameter, especially a T2* value, quantitatively. A quantitative determination delivers additional physiological information compared to conventional qualitative determination methods. The T2* value is especially well suited to being part of fMRI examinations.

In accordance with a embodiment, at least one BOLD contrast is established during the evaluation of the acquired magnetic resonance signals. BOLD contrasts are highly informative, particularly for the examination of regions of the brain.

In another embodiment, the pseudo-random stimulation sequence has a number of segments and includes a variation of at least one, at least two, or at least three of the following parameters from segment to segment: a flip angle, a phase of an RF pulse, a repetition time TR, an echo time TE, and a sampling pattern. Such a variation of recording parameters allows a very free and flexible design of the pseudo-random stimulation sequence.

In another embodiment, the acquisition of the magnetic resonance signals includes a capturing of a number of magnetic resonance raw images by a magnetic resonance fingerprinting method (MRF). The pseudo-random stimulation sequence may be employed especially well for capturing multiple magnetic resonance raw images by the MRF method, since this includes in particular that different recording parameters are set for the capturing of the different magnetic resonance raw images. Some MRF methods are known in the art.

The capturing of the number of magnetic resonance raw images, for each magnetic resonance raw image of the number of magnetic resonance raw images that may include capturing a number of locally-resolved values of the magnetic resonance signals. These locally-resolved values, referred to as signal values below, especially lie in an image area of an examination area that advantageously comprises the at least one region of the patient's brain influenced in accordance with the ways of stimulation described above. The signal values are especially not present in a k-space, the magnetic resonance raw images in such cases may not be available, on a display unit for example.

In one embodiment the evaluation of the acquired magnetic resonance signals comprises a generation of a number of magnetic resonance signal waveforms, also called MR fingerprints, from the magnetic resonance raw images. From a comparison of the number of magnetic resonance signal waveforms with a number of database signal waveforms held in a database, at least one tissue parameter is established in each case.

A number of location-dependent magnetic resonance signal waveforms may be generated via the number of magnetic resonance raw images. The different magnetic resonance signal waveforms in this case are generated via corresponding voxels of the number of magnetic resonance raw images. Corresponding voxels may have the same spatial position. Individual magnetic resonance signal waveforms may thus specify how a signal value of a voxel changes over multiple magnetic resonance raw images.

The different database signal waveforms may each be assigned a different value of the at least one tissue parameter (e.g., the MR fingerprint is characteristic of the tissue mix of the corresponding voxel). A database signal waveform may represent the signal waveform to be expected for the MRF method if a sample, of which the value of the at least one tissue parameter corresponds to the associated database value, is examined. The database signal waveforms may be established in a calibration measurement, simulated, and/or calculated. Advantageously, the database includes database signal waveforms that are to be expected when the functional magnetic resonance examination is being carried out. In particular, the database signal waveforms are tuned to the temporal sequence of the fMRI experiment to be carried out.

The MRF method then makes provision for a database signal waveform of the number of database signal waveforms to be assigned to the magnetic resonance signal waveform on the basis of the result of the signal comparison. In such cases in particular that database signal waveform of the number of database signal waveforms can be assigned to the magnetic resonance signal waveform, for example on the basis of a pattern recognition method that has the greatest similarity to the magnetic resonance signal waveform. In such cases the similarity can be established in a correlation analysis for example. The database value of the at least one tissue parameter belonging to the assigned database signal waveform can then be set as the measured value of the tissue parameter(s). The values of the one or more tissue parameters, measured at different points in the examination area, may then be stored in the tissue parameter map. The tissue parameter map may be determined locally.

The value of the at least one tissue parameter determined based on the signal comparison then represents an actual measured value, while the database values of the tissue parameter(s) represent virtual values of the tissue parameter(s). Virtual values indicate that the database values are not determined during the actual examination of the examination object but are, instead, already present in the database beforehand.

The database signal waveforms can also be assigned in each case to a number of database values of a number of tissue parameters. Then, via a signal comparison, a number of, especially quantitative values of the at least one tissue parameter can be determined simultaneously. Only the detection of a single magnetic resonance signal waveform for one voxel of the examination area is necessary in order to determine all values of the number of tissue parameters using the MRF method for the voxel. Conventional magnetic resonance fingerprinting methods are disclosed by Ma et al., Magnetic Resonance Fingerprinting, Nature 495 (2013) 187-192.

In the embodiments disclosed herein, at least one T1 value and/or one T2* value are quantitatively established as tissue parameters from the comparison of the number of magnetic resonance signal waveforms with a number of database signal waveforms stored in a database. Advantageously, possible entries in the database are thus suitable for characterizing the T1 value and/or the T2* value of the tissue by this method.

Since the BOLD contrast, as described above, is based on the change to the T2* value between deoxygenated hemoglobin and oxygenated hemoglobin, the T2* value is possibly decisive for the establishment of the activation of the at least one region of the brain. Above and beyond the change in value, for planning a therapy, the exact anatomical localization of the activation is mostly decisive, however.

In conventional fMRI measurements two separate stimulation sequences are carried out for this, namely a sequence for presenting the anatomy of the at least one brain region, for example a T1-weighted MPRage (Magnetization Prepared Rapid Acquisition Gradient Echo) sequence, and a further sequence for presenting the activation of the at least one brain region, for example a T2*-weighted EPI (Echo Planar Imaging) sequence. For evaluation, the activation map calculated on the basis of the magnetic resonance signals of the T2* weighted EPI sequence is overlaid with the anatomical imaging that is established on the basis of the magnetic resonance signals of the T1-weighted MPRage sequence.

The disclosed method thus offers the advantage that a single stimulation sequence needs to be used to establish both relevant tissue parameters T1 time and T2* time. Previously two stimulation sequences were required, e.g., the magnetic resonance signal waveforms established with the stimulation sequence may be reconciled with the database and with the aid of this reconciliation both a T1 time and also a T2* time can be established from each of these magnetic resonance signal waveforms.

In addition, a problem exists in the conventional art that the activation map and the anatomical image, as a result of the multiple different stimulation sequences, have a different distortion behavior. The resulting overlaid presentation of activation map and anatomical image has an imaging offset making the localization of the activation significantly more difficult. Activation localization is particularly difficult in the area of the nose cavities and the ears.

A distortion problem in the conventional art is avoided with the method proposed in the disclosed embodiments, since both the T2* contrast and also the T1 contrast are able to be extracted from the same MRF data, especially magnetic resonance signal waveforms. An advantage is that all extracted contrasts have exactly the same distortion behavior. The signals from which the T2* contrast and the T1 contrast are established stem from the same stimulation sequence and therefore have the same location information. Imaging offset between anatomy and activation common in the conventional use of different sequences is eliminated.

A disclosed embodiment provides the generation of first and second magnetic resonance signal waveforms. In this case, the first magnetic resonance signal waveforms are generated on the basis of acquired magnetic resonance signals from the at least one time interval with the first method of stimulation. In a similar manner, the second magnetic resonance signal waveforms are generated on the basis of acquired magnetic resonance signals from the at least one time interval with the second way of stimulation.

On the basis of the first and second magnetic resonance signal waveforms, first and second pixels are generated in each case via database comparison. A first image can be generated from the first pixels and a second from the second pixels. The images may represent tissue parameter maps, (e.g., a tissue parameter). For example, the T2* value may be represented on the basis of the pixels, visualized as color coding.

If, for example, the first way of stimulation involves a way of stimulation of an idle phase and the second way of stimulation involves a way of stimulation of an active phase, then on the basis of the first pixels an idle image and on the basis of the second pixels an active image can be created. Furthermore, by processing the first and the second pixels, an activation map and/or a t test image can be established, for example by the image recorded in the idle state and the image with neuronal activity being subtracted with the aid of a t test, a statistical method.

In other words, for determining the BOLD contrast in an fMRI experiment, two or more MR fingerprints can be created that may each be mapped for each pixel to the database and stored as a database. The first MR fingerprint corresponds to characteristic tissue properties during an idle phase of the fMRI experiment and the second MR fingerprint to the active phase.

A further embodiment generates at least one of the number of magnetic resonance signal waveforms from signals acquired within a number of time intervals of the same way of stimulation.

The acquisition of the magnetic resonance signals may be distributed for a specific way of stimulation to a number of blocks and/or time intervals of the paradigm. A block may be understood as a repeating sequence of time intervals of different ways of stimulation, such as an AB block.

Through block and/or time interval distribution, the temporal flexibility is increased. A greater number of images (e.g., record images of a number of slices of the at least one region of the patient's brain) may be generated than the number of images possible using magnetic resonance signals of only one block and/or time interval of limited duration. The duration of the block and/or time interval is often produced from the objective and/or strategy and/or planning of the fMRI experiment.

Magnetic resonance signal waveforms may be generated from magnetic resonance signals that are acquired within a single time interval.

The acquisition of a magnetic resonance signal waveform or MR fingerprint can possibly be done entirely on the basis of magnetic resonance signals of one time interval, for example an idle phase or an active phase. If the functional magnetic resonance examination includes a generation of a number of images that especially image a number of slices of the at least one region of the patient's brain, the magnetic resonance signal waveforms of a part of the images can be derived for example on the basis of magnetic resonance signals from a first time interval and the magnetic resonance signal waveforms of further images on the basis of magnetic resonance signals from one or more further time intervals.

Thus, for example the magnetic resonance image waveforms of the pixels in some cases, all pixels, of images of a first and a second slice can be established from magnetic resonance signals from a first active phase and the magnetic resonance image waveforms of the pixels, in some cases, of all pixels, of images of a third and a fourth slice can be established from magnetic resonance signals from a second active phase.

It is further proposed that a processor unit be provided with at least one input parameter as a function of the first and/or second way of stimulation. On the basis of this at least one input parameter the processor unit creates a pseudo-random stimulation sequence that is embodied, by switching a gradient coil unit, to create acoustic signals for influencing the at least one region of the patient's brain in accordance with the first and/or second way of stimulation.

Through the switching of the gradient coil unit, magnetic fields are switched over rapidly. The electromagnetic forces act on anchorages and/or fastenings of the gradient coil unit such that acoustic waves perceptible for a living being can be produced. In addition, the magnetic resonance device or parts of the magnetic resonance device can act as a resonator, through which the acoustic waves are influenced. The magnetic resonance device can thus act in a similar way to a loudspeaker.

The loud noises often arising in conventional fMRI experiments represent a not-insignificant problem. However, loud noises may have an undesirable effect on brain activity, as known in the conventional art. Through the pseudo-random design of the stimulation sequence, as allowed for example by the MRF methods, degrees of freedom are produced that may significantly influence the development of noise of the sequence. It is known that the development of noise can be altered to the effect of reproducing music. The embodiments disclosed herein provide for explicit creation of acoustic signals for presentation of paradigms in fMRI examination. Thus, the development of noise does not represent an unintended noise stimulus but, instead, a useful component of the fMRI examination.

Input parameters include data, (e.g., digitized data), including acoustic information, such as files in an MP3 or MIDI (Musical Instrument Digital Interface) format. Parameters such as tone level, tone duration, volume, dynamic, sound color etc, may be input via a user interface. In addition, acoustic signals can be recorded and/or provided via a microphone as input parameters. Further possibilities are known to the person skilled in the art.

The processor unit advantageously creates, on the basis of the at least one input parameter, a pseudo-random stimulus sequence, creating the acoustic signals corresponding to the at least one input parameter during the fMRI examination. That is, he processor unit may translate the at least one input parameter into a suitable pseudo-random stimulation sequence.

The processor unit can be included in the magnetic resonance device carrying out the functional magnetic resonance examination. Alternatively, the magnetic resonance device may be independent of the processor unit. The processor unit may be a part of a computation unit that creates the pseudo-random stimulation sequence. Switching of a gradient coil unit, may be used to create acoustic signals for influencing the at least one region of the patient's brain in accordance with the various ways of stimulation. After the creation of the stimulation sequence, the sequence may be transferred to the magnetic resonance device for carrying out the functional magnetic resonance examination.

In some embodiments a time interval includes an active phase and at least one further time interval comprises an idle phase. The at least one region of the brain is activated more strongly by the created acoustic signals during the active phase than in the idle phase.

Thus, noise generated by the stimulation sequence that has a calming influence on the patient is selected for the idle phase for example, e.g., the stimulus supplied to the patient can be suitable for reducing a concentration of deoxygenated hemoglobin in the at least one region of the brain.

To influence the at least one region of the patient's brain, at least a part of the acoustic signals is embodied as at least one word able to be perceived acoustically for the patient and/or causes the patient to carry out an activity and/or is embodied as music and/or tones.

The noise generated during individual time intervals (e.g., an active phase), may be differentiated from other time intervals, (e.g., an idle phase). Thus, the differentiated noises signal to a patient when he or she is to perform a certain task. Accordingly, the paradigm may be presented acoustically. Speech paradigms may be generated, e.g., generating sentences in an active phase including instructions for the patient to complete. Tones and/or music may also or, alternatively, be included.

One embodiment provides acoustic signals that are created by the suitable switching of at least one gradient coil to be synchronized by a synchronization unit with at least one further stimulus that is supplied to the patient.

The at least one further stimulus configures the way of stimulation within the framework of the functional magnetic resonance examination, e.g., for stimulus presentation. The at least one further stimulus may be a visual and/or haptic and/or acoustic and/or olfactory and/or gustatory and/or electrical stimulus. A further acoustic stimulus is also conceivable that does not occur through the switching of the gradient pulses.

The further stimulus can be provided by a corresponding device. For example, a visual stimulus may be supplied to the patient by a light source and/or a monitor and/or a projector, possibly using a mirror system. The point in time and/or period of time at which such a stimulus is supplied can be synchronized with the stimulus sequence via a synchronization unit. However, a person, especially medical personnel, can also initiate a stimulus, wherein the point in time and/or the period of time at which the stimulus is to be created can be displayed to the person, e.g., via a display device, such as a monitor.

At least a part of the acoustic signals may be configured to depend on optical stimuli. Inter alia, an expression of emotions may be realized by the sequence. Thus, for example, a presentation of pictures with people who are happy or sad can be supported by the background noise of the sequence. Achieving noise generation by the sequence that is no longer perceived as interference noise is especially advantageous. Also, in a possible presentation of films, an encoding of the film noises by the sequence is conceivable, so that a disruptive influence of the noise generated by the sequence is advantageously suppressed.

A disclosed magnetic resonance device for recording and evaluating magnetic resonance signals of a functional magnetic resonance examination a patient is described below. Advantages also correspond to the advantages of the disclosed method for recording and evaluating magnetic resonance signals of a functional magnetic resonance examination of a patient that have been described in detail above. Features, advantages or alternate forms of embodiment mentioned here can likewise be transferred to the other claimed subject matter and vice versa. In other words, the physical claims can also be further developed with the features described or claimed in conjunction with a method. The corresponding functional features of the method are embodied in such cases by corresponding physical modules, especially by hardware modules.

An embodiment of the magnetic resonance device for recording and evaluating magnetic resonance signals of a functional magnetic resonance examination of a patient includes an interface for influencing at least one region of the patient's brain; a radio frequency antenna unit and a gradient coil unit for stimulation and acquisition of magnetic resonance signals; and a system control unit for evaluation of the acquired magnetic resonance signals.

The interface for influencing at least one region of the patient's brain can be embodied to transmit information that serves such that, at the correct point in time and/or in the correct period of time, the stimulus occurs to influence at least one region of the patient's brain in accordance with a desired way of stimulation.

For example, medical personnel can be notified via the interface that in a specific period of time a specific stimulus is to be supplied to the patient, for example by the medical personnel requesting that the patient performs a specific activity. In this case, the interface maybe embodied as a screen communicating information to the medical personnel. Corresponding control signals may also be sent via the interface to a screen.

In particular, the interface may connect an external device for creating at least one stimulus thereto, wherein the magnetic resonance device is embodied to exchange control signals via the interface with the external unit. Thus, there can be an exchange of information between an external device and the magnetic resonance device via the interface. Synchronization units are conceived that synchronize the execution of the sequence with the influencing of the at least one region of the patient's brain via the interface. The synchronization unit can be included in the magnetic resonance device. In this case the synchronization unit may send control signals via this interface to the external device that causes the external device (e.g., a projector) to supply stimuli to the patient in tune with the stimulation sequence.

However, the synchronization unit maybe an external device. In this case, the external synchronization unit sends control signals to the magnetic resonance device via the interface, in order to control the timing of the functional magnetic resonance examination and to be in tune with and/or synchronize with the timing of a further external device, such as a projector.

In another embodiment, the magnetic resonance device additionally has a processor unit that is embodied, on the basis of at least one input parameter, to create a pseudo-random stimulation sequence that is embodied, through suitable switching of a gradient coil unit. Acoustic signals are created for explicit influencing of the at least one region of the patient's brain.

A further embodiment makes provision for the magnetic resonance device to be embodied to carry out a method using a magnetic resonance fingerprinting method. A signal waveform generation unit may be embodied to generate a magnetic resonance signal waveform of an examination area of a patient, (e.g., region of the brain) by a magnetic resonance fingerprinting method. The system control unit, especially a comparison unit of the system control unit, can be embodied for a signal comparison of the acquired magnetic resonance signal waveform with a number of database signal waveforms stored in a database. Each of the database signal waveforms is assigned a database value of at least one tissue parameter. Furthermore, the system control unit can be embodied for determining a value of the at least one tissue parameter on the basis of the signal comparison.

A computer program product is also provided, including a program that may be loaded directly into a memory of a programmable system control unit of a magnetic resonance device and has program capabilities, e.g. libraries and auxiliary functions, for executing the disclosed methods when the computer program is executed in the system control unit of the magnetic resonance device.

In such cases the computer program product can be software with a source code that still has to be compiled and linked or that only has to be interpreted. The computer program product can include executable software code that may be loaded into the system control unit for execution. The computer program product enables the disclosed method to be executed quickly, in an identically repeatable way and robustly. The computer program product is configured to execute the disclosed method by the system control unit. In such cases, the system control unit may have the corresponding requirements (e.g., a corresponding main memory, a corresponding graphics card, or a corresponding logic unit), so that the method can be executed efficiently. The computer program product may be stored on a computer-readable medium, a network, or server that may be loaded into the processor of a local system control unit directly connected to or integrated with the magnetic resonance device. Furthermore, control information of the computer program product can be stored on an electronically-readable data medium. The control information of the electronically-readable data medium can be configured so that, when the data medium is used in a system control unit of a magnetic resonance device, the data medium, in conjunction with the system control unit, execute the disclosed embodiments of the method. Examples of electronically-readable data media are a DVD, a magnetic tape or a USB stick. Electronically-readable control information, in particular software, is stored on the electronically-readable data media. If this control information is read from the storage medium and stored in a system control unit of a magnetic resonance device, all disclosed embodiments of the previously described method can be carried out. The disclosed embodiments may thus be based on the said computer-readable medium and/or on the said electronically-readable data medium.

Further advantages, features and details of the invention emerge from the exemplary embodiments described below, as well as with reference to the drawings.

The scope of the present invention is defined solely by the appended claims and is not affected to any degree by the statements within this summary. The present embodiments may obviate one or more of the drawbacks or limitations in the related art.

### DESCRIPTION OF THE FIGURES

FIG. 1 shows an embodiment of a magnetic resonance device in a schematic diagram,

FIG. 2 shows a block diagram of an example method for recording and evaluating magnetic resonance signals of a functional magnetic resonance examination of a patient,

FIG. 3 shows a block diagram of one embodiment of a method for evaluating magnetic resonance signals according to a magnetic resonance fingerprinting method,

FIG. 4 shows schematic diagrams of example sampling patterns for functional magnetic resonance examinations according to the prior art,

FIG. 5 shows a schematic diagram of an example sampling pattern for functional magnetic resonance examinations,

FIG. 6 shows an example paradigm with six time intervals in a schematic diagram

FIG. 7 shows a block diagram of one embodiment of a method for creating a pseudo-random stimulation sequence for explicit generation of acoustic signals by the gradient coil unit, and

FIG. 8 shows a schematic diagram of an example divided acquisition of magnetic resonance signals.

### DETAILED DESCRIPTION

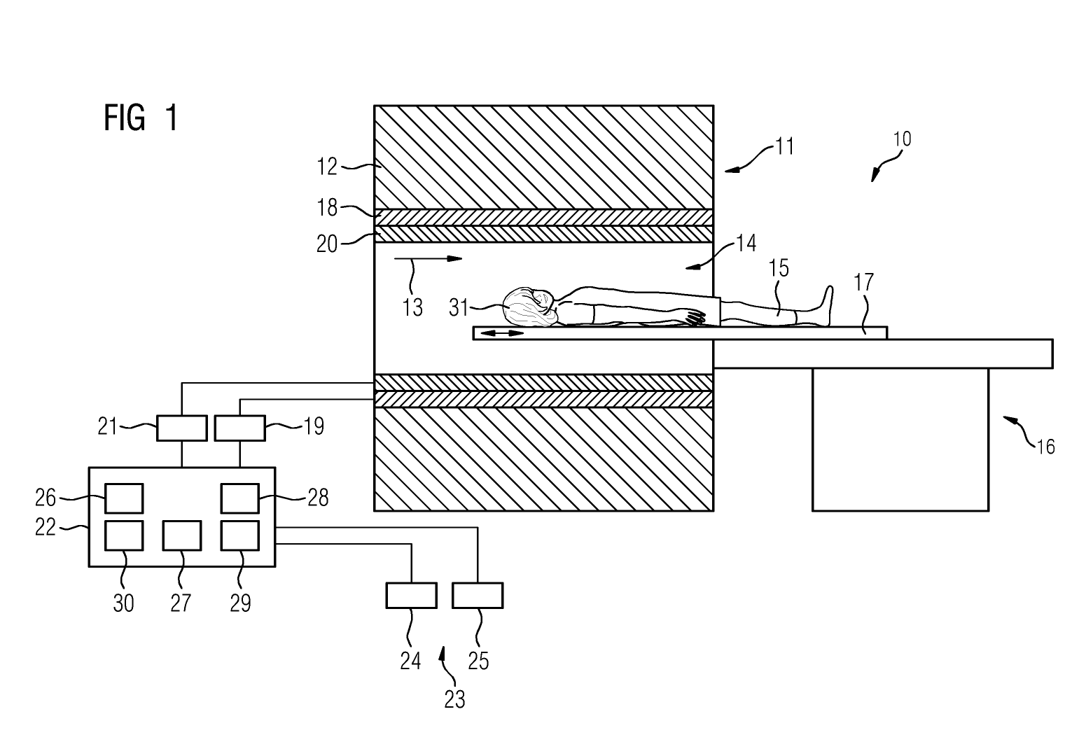

FIG. 1 shows a schematic diagram of a magnetic resonance device 10. The magnetic resonance device 10 comprises a magnet unit 11 including a superconducting main magnet 12 for creating a strong and especially constant main magnetic field 13. In addition, the magnetic resonance device 10 has a patient receiving area 14 for receiving a patient 15 with brain region 31. In one embodiment, the patient receiving area 14 is embodied in a cylindrical shape and is surrounded in a circumferential direction by the magnet unit 11 in a cylindrical shape. Other embodiments of the patient receiving area 14 may be embodied in many other shapes. The patient 15 can be pushed by a patient support device 16 of the magnetic resonance device 10 into the patient receiving area 14. The patient support device 16 has a patient table 17 that is movable within the patient receiving area 14.

The magnet unit 11 further has a gradient coil unit 18 for creating magnetic field gradients that are used for local encoding during imaging. The gradient coil unit 18 may include at least one, three, or other number of gradient coils (not shown in detail here) that are fastened to the magnet unit 11. The gradient coil unit 18 is controlled and/or switched by a gradient control unit 19 of the magnetic resonance device 10. During the switching of the gradient coil unit 18, high mechanical forces may act on the fastening of the at least one gradient coil that may result in the generation of noise perceptible for the patient 15.

The magnet unit 11 further has a radio-frequency antenna unit 20 configured as a body coil integrated into the magnetic resonance device 10. The radio-frequency antenna unit 20 is configured to excite a polarization that is produced in the main magnetic field 13 created by the main magnet 12. The radio-frequency antenna unit 20 is controlled by a radio-frequency antenna control unit 21 of the magnetic resonance device 10 and irradiates radio-frequency pulses into an examination space that is formed by a patient receiving area 14 of the magnetic resonance device 10. The radio-frequency antenna unit 20 is further embodied for receipt and/or acquisition of magnetic resonance signals.

To control the main magnet 12, the gradient control unit 19 and to control the radio-frequency antenna control unit 21, the magnetic resonance device 10 has a system control unit 22. The system control unit 22 centrally controls the magnetic resonance device 19, such as the carrying out of a pre-determined imaging, especially pseudo-random, stimulation sequence. Furthermore, magnetic resonance device 10 includes a user interface 23 that is connected to the system control unit 22. Control information, such as imaging parameters, as well as reconstructed magnetic resonance images, may be displayed on a display unit 24, for example on at least one monitor, of the user interface 23 for medical operating personnel. The user interface 23 may have an input unit 25, so that the information and/or parameters can be entered by the medical operating personnel during a measurement process.

The magnetic resonance device 10 further includes an interface 30 for influencing at least one brain region 31 of the patient 15. The interface 30 can be embodied to transmit information that serves to insure that the at least one brain region 31 of the patient 15 is influenced according to a desired way of stimulation at the right time and/or in the right period of time.

For example, the medical operating personnel may be notified via the interface 30 that the patient is to be supplied with a specific stimulus at certain time. The medical operating personnel may request that the patient 15 performs a certain activity. In this case, the display unit 24 can be supplied with control signals via the interface 30, providing an indication to the medical operating personnel.

In particular, the interface 30 can be embodied to connect an external device (not shown) to create at least one stimulus. The system control unit 22 is embodied to exchange control signals with the external unit via the interface 30. Information may also be exchanged between an external device and the magnetic resonance device 10 via the interface. For example, a synchronization unit 27 may synchronize the execution of the sequence with the influencing of the at least one region of the patient's brain via the interface 30. The synchronization unit 27 may be included in the magnetic resonance device. The synchronization unit 27 may send control signals via this interface to the external device that may cause the external device, (e.g., a projector) to supply the patient 15 with stimuli tuned to the stimulation sequence.

Unlike the embodiment shown in FIG. 1, the synchronization unit may be an external device. In this case, the external synchronization unit may send control signals to the magnetic resonance device 10 via the interface 30 in order to control timing of the functional magnetic resonance examination. Timing may be controlled to be in tune with and/or synchronize with the timing of a further external device, such as a projector.

In one embodiment, the magnetic resonance device 10 additionally includes a processor unit 26 that is embodied, on the basis of at least one input parameter, to create a pseudo-random stimulation sequence by the suitable switching of a gradient coil unit 18 to create acoustic signals for explicit influencing of the at least one brain region 31 of the patient 15.

One embodiment makes provision for the magnetic resonance device 10 to be embodied to carry out a disclosed method using a magnetic resonance fingerprinting method. A possible signal waveform generation unit 28 is embodied to generate a magnetic resonance signal waveform of an examination area of a patient (e.g., brain region) via a magnetic resonance fingerprinting method. The system control unit 22, especially a comparison unit 29 of the system control unit 22, is embodied for a signal comparison of the acquired magnetic resonance signal waveform. A number of database signal waveforms are stored in a database, and each of the database signal waveforms is assigned a database value of at least one tissue parameter. Furthermore, the system control unit 22 is embodied for determining a value of the at least one tissue parameter on the basis of the signal comparison.

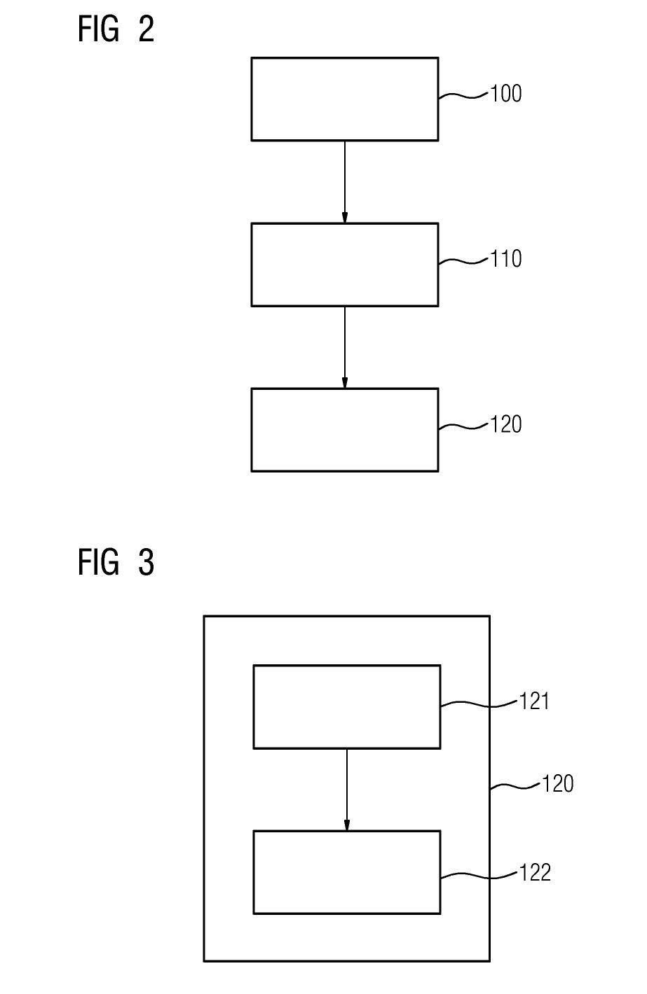

The magnetic resonance device 10, including the magnet unit 11, is configured, together with the system control unit 22, for carrying out a method for recording and evaluating magnetic resonance signals of a functional magnetic resonance examination of a patient 15, depicted schematically in FIG. 2. To this end, the system control unit 22 has appropriate software or computer programs that are able to be loaded into a memory of the system control unit 22. System control unit 22 includes processing capabilities for carrying out the method for recording and evaluating magnetic resonance signals of a functional magnetic resonance examination of a patient when the program is executed in the system control unit 22 of the magnetic resonance device 10.

FIG. 2 shows an embodiment of the method. In act 100, the at least one brain region 31 of the patient 15 is influenced within at least two time intervals. The brain is influenced within a first time interval according to a first way of stimulation and within a second time interval according to a second way of stimulation that differs from the first way of stimulation.

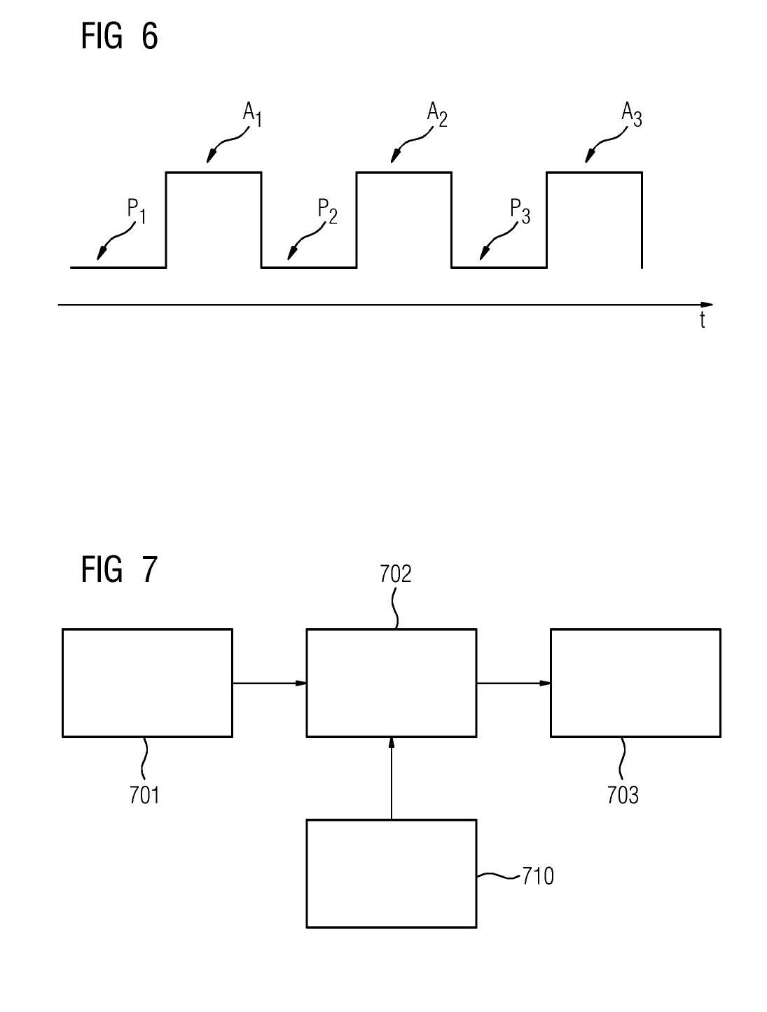

An example of a sequence of time intervals is depicted in FIG. 6, as a block paradigm. In this figure, a time axis t is plotted horizontally. The paradigm includes three blocks, each with two time intervals, which can also be referred to as epochs. The time intervals P₁ and A₁ form the first block; the time intervals P₂ and A₂ form the second block; and the time intervals P₃ and A₃ form the third block. fMRI examinations with more or fewer time intervals are also possible. The durations of the time intervals may be the same, partly different, or entirely different. The at least one brain region 31 of the patient 15 is influenced in time interval P₁ according to a first way of stimulation and in time interval A₁ according to a second way of stimulation. The first way of stimulation is repeated in the time intervals P₂ and P₃, and the second way of stimulation is repeated in time intervals A₂ and A₃. The time intervals P₁, P₂, and P₃ may represent idle phases. The time intervals A₁, A₂, and A₃ may represent active phases. Moreover, fMRI examinations may include more than two types of stimulation, (e.g., one idle phase and two active phases). Each of the phases may have a different way of stimulation, (e.g., a total of three types of ways of stimulation for the previous example).

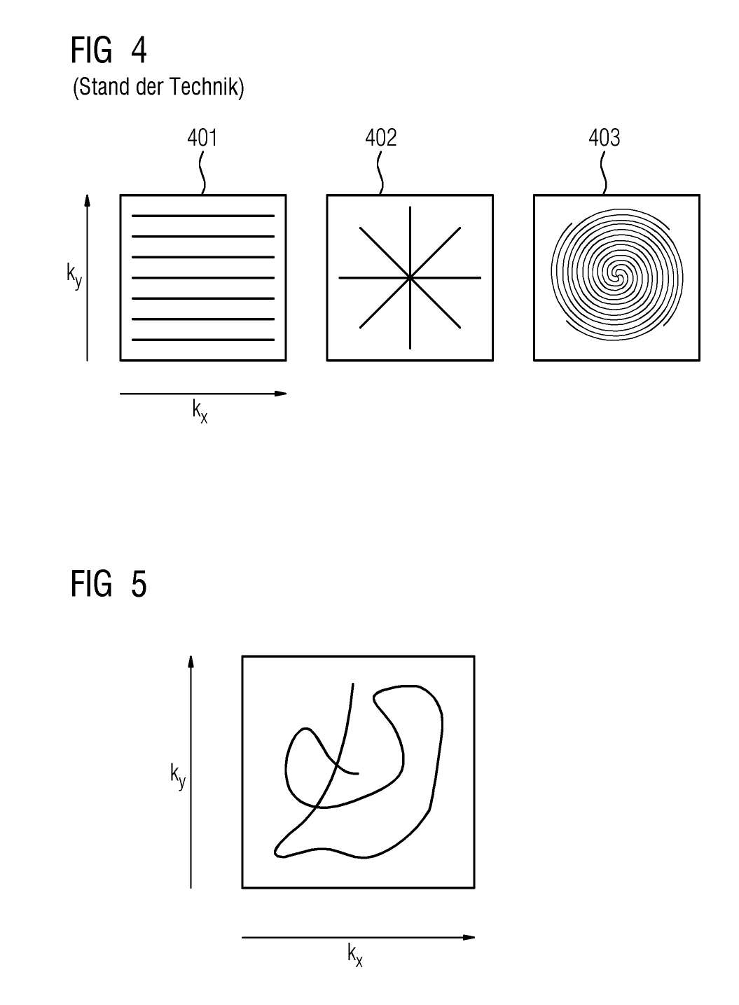

In an act 110 of FIG. 2, magnetic resonance signals are acquired from the at least one brain region 31 of the patient 15. The acquisition of magnetic resonance signals may be concurrent and/or partly offset in time with the influencing of the at least one brain region of the patient 100. The magnet unit 11 is operated according to a pseudo-random stimulation sequence that is explained in greater detail with reference to FIGS. 4 and 5. Conventional k-space sampling patterns such as a Cartesian 401, radial 402, and spiral-shaped 403 sampling pattern, are shown in FIG. 4. Other known sampling patterns (not shown) include: propeller-shaped, rosette-shaped or zigzag shaped patterns. In FIG. 5, a sampling pattern of a pseudo-random stimulation sequence that has a completely irregular structure is depicted. In contrast, the sampling patterns in FIG. 4 exhibit a clearly recognizable regularity. In addition, pseudo-random stimulation sequences may also include a variation of at least one flip angle, at least one phase of an RF pulse, at least one repetition time TR, and/or at least one echo time TE. The disclosed pseudo-random stimulation sequence also thus differs from stimulation sequences of conventional fMRI examinations.

The acquired magnetic resonance signals are evaluated in an act 120.

The method may be carried out via a magnetic resonance fingerprinting method. The acquisition of the magnetic resonance signals from the at least one brain region 31 of the patient 15 includes, in act 110, a recording of a number of magnetic resonance raw images via a magnetic resonance fingerprinting method. An optional evaluation 120 in accordance with the magnetic resonance fingerprinting method is shown in FIG. 3. In an act 121, a number of magnetic resonance signal waveforms are generated from the number of magnetic resonance raw images.

In particular, at least one first and one second magnetic resonance signal waveform may be generated. The first magnetic resonance signal waveform is generated on the basis of acquired magnetic resonance signals from the at least one time interval with the first way of stimulation. The second magnetic resonance signal waveform is generated on the basis of acquired magnetic resonance signals from the at least one time interval with the second way of stimulation.

In the context of FIG. 6, the at least one first magnetic resonance signal waveform may be generated on the basis of magnetic resonance signals recorded within the time interval P₁ and the at least one second magnetic resonance signal waveform on the basis of magnetic resonance signals that were recorded within the time interval A₁. On the basis of the magnetic resonance signals recorded within the time intervals P₁ and A₁, one magnetic resonance signal waveform be generated in each case in addition to the generation of a number may be generated in each case. Imaging of the at least one brain region may include of a number of pixels, wherein advantageously at least one magnetic resonance signal waveform is generated for each pixel.

It is further conceivable for at least one of the number of magnetic resonance signal waveforms to be generated on the basis of magnetic resonance signals acquired within a number of time intervals of the same way of stimulation.

For example, in FIG. 6, for the idle phases P₁, P₂ and P₃, four slices of the at least one brain region 31 of the patient 15, one image is to be generated in each case. Each of the four images to be generated includes a number of pixels in this example, the number of which is 256² in each case for example. In this case each pixel is derived from at least one magnetic resonance signal waveform. Thus, for the four slices, a total of four times 256² magnetic resonance signal waveforms would have to be specified. One magnetic resonance signal waveform includes signal values that result for magnetic resonance raw images. The magnetic resonance raw images are created on the basis of acquired magnetic resonance signals.

A first part of the signal values for determining one of the 4×256² magnetic resonance signal waveforms can result from magnetic resonance signals that were recorded within the idle phase P₁, a second part can result from magnetic resonance signals that were recorded within the idle phase P₂, etc. A first part of the signal values for determining a further of the 4×256² magnetic resonance signal waveforms may again result from magnetic resonance signals recorded within the idle phase P₁, a second part can result from magnetic resonance signals recorded within the idle phase P₂, etc. Additional images may also be generated in the same manner, relating to the active phases A₁, A₂, and A₃. Splitting the creation of the magnetic resonance signal waveforms increases the flexibility, in order to acquire a larger number of slices for example.

At least one of the number of magnetic resonance signal waveforms may be generated on the basis of magnetic resonance signals acquired within a single time interval.

Using FIG. 6, for example, all magnetic resonance signal waveforms for creation of two of the four slice images may be derived from magnetic resonance signals that were acquired within the time interval P₁. All magnetic resonance signal waveforms for creation of the two remaining slice images may be derived from magnetic resonance signals acquired within the time interval P₂.

A part of the magnetic resonance signal waveforms may be created on the basis of acquired magnetic resonance signals from a number of time intervals. Another part may be created on the basis of acquired magnetic resonance signals from only one time interval.

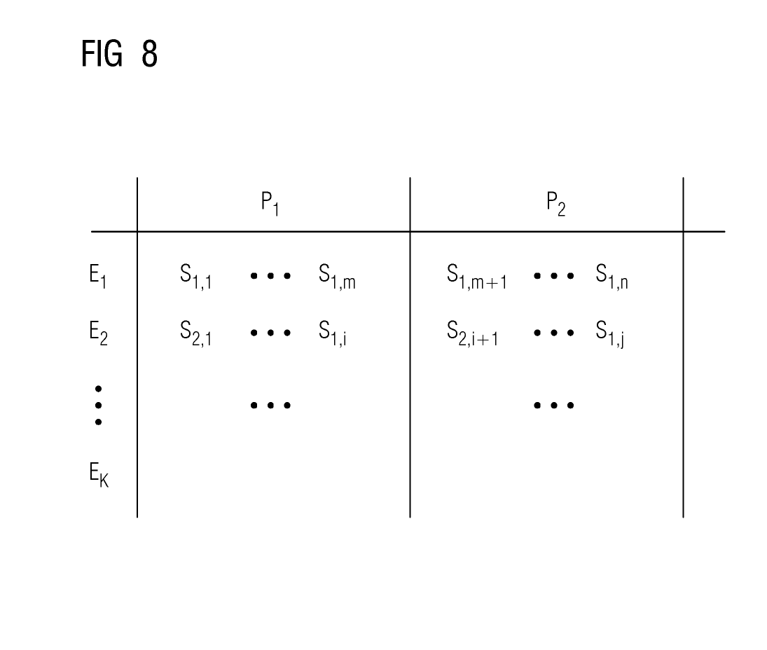

FIG. 8 also illustrates an example of how magnetic resonance signal waveforms are established from magnetic resonance signals recorded in a number of time intervals. For example, an image of a slice that contains k pixels is to be generated, so that k magnetic resonance signal waveforms E1 to EK are to be established. Each k magnetic resonance signal waveform includes a number of signal values. For example, the magnetic resonance signal waveform E1 includes n signal values S1,1 to S1,n and the magnetic resonance signal waveform E2 includes j signal values S2,1 to S2,j. The value, n, may be equal to j or not equal to j. The detection of the signal values can be divided up over a number of time intervals that may be separated from one another in time by one or more further time intervals. In the example shown here, the signal values are detected for the magnetic resonance signal waveforms E1 and E2 in the two time intervals P₁ and P₂. Thus, for the magnetic resonance signal waveform E1, a first part of the signal values S1,1 to S1,m can be recorded within the time interval P₁. A second part of the signal values S1,m+1 to Si,n can be recorded within the time interval P₂. For the magnetic resonance signal waveform E2, in a similar way, a first part of the signal values S2,1 to Sl,i can be recorded within the time interval P₁ and a second part of the signal values S2,i+1 to S2,j can be recorded within the time interval P₂. The value, m, can be equal to i or not equal to i.

The derivation of the pixels for the magnetic resonance signal waveforms can be done on the basis of at least one tissue parameter. As illustrated in FIG. 3 in act 122, at least one tissue parameter is established by the number of magnetic resonance signal waveforms being compared with a number of database magnetic resonance signal waveforms stored in a database.

In such cases, T1 and t2* values are advantageously established and are especially suitable for fMRI experiments. In conventional fMRI experiments, T1 and t2* values are each recorded in separate measurement processes. With the disclosed method, both T1 and t2* values may be recorded in a single measurement process, since a number of tissue parameters can be established simultaneously with the magnetic resonance fingerprinting method.

A BOLD contrast may be established from the T2* values, allowing conclusions to be drawn about brain activity. In particular, an activity map may be created from the T2* values. When related to the case shown in FIG. 6, an image based on T2* values can be generated from the magnetic resonance signals acquired in the idle phases P₁, P₂, and P₃, as well as a further image on the basis of the magnetic resonance signals acquired in the active phases A₁, A₂, and A₃. By differentiating the pixel values of the two images from idle and active phase that may include methods known to the person skilled in the art, an activity map can be established.

On the basis of T1 values the anatomy of the patient 15, and thus also of the at least one region of the brain 31, can be shown. The activity map may be linked to the anatomy data, by being superimposed in a picture. The T2* and T1 values corresponding to each other have the same location information, since both are derived from the same acquired magnetic resonance signals. Therefore, the superimposition can be realized easily by the disclosed method, because no presentation offset between activity and anatomy data results.

FIG. 7 shows a diagram that illustrates a creation of a pseudo-random stimulation sequence by switching a gradient coil unit, to create acoustic signals for influencing the at least one region of the patient's brain in accordance with the first and/or second way of stimulation. A provision 701 of at least one input parameter, depending on the first and/or second way of stimulation, is carried out at a processor unit. Advantageously, the at least one input parameter includes acoustic information, such as an audio file (e.g., an MP3 or MIDI file). Parameterization of acoustic information can also be done via a correspondingly configured input interface, via a sequence of sounds, tones, noises of a desired duration and/or volume and/or frequency and/or sound coloration is defined. The at least one input parameter may be entered via the user interface 23.

Through the computing operation 702, via the processor unit, the pseudo-random stimulation sequence is computed. An output 703 of the pseudo-random stimulation sequence follows that may be used by the magnetic resonance device 10. Further boundary conditions 710, in addition to the at least one input parameter provided, may be included in the computing operation 702, such as an acoustic resonance behavior of the magnetic resonance device 10.

The processor unit may, as shown in FIG. 1, be included in the system control unit 22 of the magnetic resonance device 10. However, the processor unit may also be included in an external device, wherein advantageously the pseudo-random stimulation sequence output is transmitted for use on the magnetic resonance device 10 for example with the aid of a network connection or a data medium (e.g., a USB stick).

With the aid of the acoustic waves that are created by the operation of the gradient coil unit 18 in accordance with the computed and output pseudo-random stimulation sequence, explicit stimuli can be supplied to the patient 15. For example, music, a noise, and/or a spoken word can be reproduced, influencing the at least one brain region 31 of the patient 15. Furthermore, e.g. during an idle phase, a noise may be caused to be generated that has a calming effect on the patient 15. The noise generated in an active phase may be differentiated from noises generated in an idle phase. Accordingly, the patient is made aware of when a certain task is to be performed. In particular, the created acoustic signals may be synchronized by the synchronization unit 27 with at least one further stimulus.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for recording and evaluating magnetic resonance signals of a functional magnetic resonance imaging examination of a patient, the method comprising:
influencing at least one region of a brain of the patient within at least two time intervals,
wherein the influencing is undertaken within a first time interval of the at least two time intervals via a first way of stimulation,
wherein the influencing is undertaken within a second time interval of the at least two time intervals via a second way of stimulation, and
wherein the first and the second way of stimulation differ from one another;
acquiring magnetic resonance signals from the at least one region of the brain via a pseudo-random stimulation sequence during the at least two time intervals; and
evaluating the acquired magnetic resonance signals.

2. The method of claim 1, wherein at least one Blood Oxygenation Level Dependent (BOLD) contrast is established during the evaluation of the acquired magnetic resonance signals.

3. The method of claim 1, wherein the pseudo-random stimulation sequence comprises:
a plurality of segments; and
a variation of at least one of the following parameters from segment to segment: a flip angle, a phase of an RF pulse, a repetition time TR, echo time TE, or a sampling pattern.

4. The method of claim 1, wherein acquiring the magnetic resonance signals comprises:
capturing a plurality of magnetic resonance raw images via a magnetic resonance fingerprinting method.

5. The method of claim 4, wherein evaluating the acquired magnetic resonance signals comprises:
generating a plurality of magnetic resonance signal waveforms from the plurality of magnetic resonance raw images; and
establishing at least one tissue parameter based on the comparison of the plurality of magnetic resonance signal waveforms based on a plurality of database signal waveforms stored in a database.

6. The method of claim 5, wherein at least one t1 value, a T2* value, or at least one t1 value and a T2* value is established as a tissue parameter based on the comparison of the plurality of magnetic resonance signal waveforms with a plurality of database signal waveforms held in a database.

7. The method of claim 5,
wherein the first magnetic resonance signal waveforms are generated on the basis of acquired magnetic resonance signals from the at least one time interval with the first way of stimulation, and
wherein the second magnetic resonance signal waveforms are generated on the basis of acquired magnetic resonance signals from the at least one time interval with the second way of stimulation.

8. The method of claim 5, wherein at least one of the plurality of magnetic resonance signal waveforms is generated on the basis of magnetic resonance signals acquired within a plurality of time intervals of the same way of stimulation.

9. The method of claim 5, wherein at least one of the plurality of magnetic resonance signal waveforms is generated on the basis of magnetic resonance signals acquired within a single time interval.

10. The method of claim 1,
wherein a processor unit is supplied with at least one input parameter depending on the first way of stimulation, the second way of stimulation, or the first way of stimulation and the second way of stimulation,
wherein the processor unit creates a pseudo-random stimulation sequence on the basis of the at least one input parameter, which is embodied, by switching a gradient coil unit, to create acoustic signals for influencing the at least one region of the patient's brain in accordance with the first way of stimulation, the second way of stimulation, or the first way of stimulation and the second way of stimulation .

11. The method of claim 10,
wherein at least one time interval includes an active phase and at least one other time interval includes an idle phase, and
wherein the at least one region of the brain is more strongly activated by the created acoustic signals in the active phase than the at least one region of the brain in the idle phase.

12. The method of claim 10,
wherein at least a part of the acoustic signals is embodied as a word acoustically perceptible for the patient, a word that causes the patient to perform an activity, or a word acoustically perceptible for the patient that causes the patient to perform an activity, music, a plurality of tones, or music and a plurality of tones.

13. The method of claim 10,
wherein the acoustic signals created by the suitable switching of the at least one gradient coil, are synchronized by means of a synchronization unit with at least one further stimulus supplied to the patient.

14. A magnetic resonance device for recording and evaluating magnetic resonance signals of a functional magnetic resonance imaging examination of a patient, the device comprising:
an interface influencing at least one region of the patient's brain at least two time intervals,
wherein the influencing is undertaken within a first time interval of the at least two time intervals via a first way of stimulation, and
wherein the influencing is undertaken within a second time interval of the at least two time intervals in accordance with a second way of stimulation;
a radio-frequency antenna unit;
a gradient coil unit, wherein the radio-frequency antenna unit and the gradient coil unit stimulate and acquire magnetic resonance signals; and
a system control unit evaluating the acquired magnetic resonance signals.

15. A computer program product which comprises a program and is able to be loaded directly into a memory of a programmable system control unit of a magnetic resonance device, with instructions causing the magnetic resonance device to:
influence at least one region of the brain of the patient within at least two time intervals,
wherein the influence is undertaken within a first time interval of the at least two time intervals via a first way of stimulation,
wherein the influence is undertaken within a second time interval of the at least two time intervals via a second way of stimulation, and
wherein the first and the second way of stimulation differ from one another;
acquire magnetic resonance signals from the at least one region of the brain via a pseudo-random stimulation sequence during the at least two time intervals; and
evaluate the acquired magnetic resonance signals.

16. The method of claim 2, wherein the pseudo-random stimulation sequence comprises:
a plurality of segments; and
a variation of at least one of the following parameters from segment to segment: a flip angle, a phase of an RF pulse, a repetition time TR, echo time TE, and a sampling pattern.

17. The method of claim 2, wherein acquiring the magnetic resonance signals comprises:
capturing a plurality of magnetic resonance raw images via a magnetic resonance fingerprinting method.

18. The method of claim 3, wherein acquiring the magnetic resonance signals comprises:
capturing a plurality of magnetic resonance raw images via a magnetic resonance fingerprinting method.

19. The method of claim 6,
wherein the first magnetic resonance signal waveforms are generated on the basis of acquired magnetic resonance signals from the at least one time interval with the first way of stimulation, and
wherein the second magnetic resonance signal waveforms are generated on the basis of acquired magnetic resonance signals from the at least one time interval with the second way of stimulation.

20. The method of claim 6, wherein at least one of the plurality of magnetic resonance signal waveforms is generated on the basis of magnetic resonance signals acquired within a plurality of time intervals of the same way of stimulation.
